(19) United States
(12) Patent Application Publication
(10) Pub. No.: US 2023/0048817 A1
(43) Pub. Date: Feb. 16, 2023

(54) DISPLAY DEVICE AND METHOD OF MANUFACTURING THE SAME

(71) Applicant: Samsung Display Co., LTD., Yongin-si (KR)

(72) Inventors: Keunwoo KIM, Seongnam-si (KR); Taewook KANG, Seongnam-si (KR); Jaeseob LEE, Seoul (KR); Sanggun CHOI, Suwon-si (KR)

(73) Assignee: Samsung Display Co., LTD., Yongin-si (KR)

(21) Appl. No.: 17/719,849

(22) Filed: Apr. 13, 2022

(30) Foreign Application Priority Data
Aug. 12, 2021 (KR) 10-2021-0106900
Oct. 29, 2021 (KR) 10-2021-0146943

(51) Int. Cl. H01L 27/32; H01L 51/56

(52) U.S. Cl. CPC H01L 27/3265; H01L 51/56; H01L 2227/323; G09G 3/3233

(57) ABSTRACT

A display device includes a first active layer disposed on a substrate and including a source area, a resistance area, and a drain area spaced apart from the source area by the resistance area, a first gate electrode and a second gate electrode disposed on the first active layer and overlapping the first active layer, and a first power voltage electrode disposed on the first gate electrode and the second gate electrode and overlapping the resistance area in a cross-sectional view. In this case, the resistance area of the active layer and the first power voltage electrode may form a floating node capacitor. Accordingly, in a case that the first gate electrode and the second gate electrode form a dual gate transistor with the active layer, an instantaneous voltage increase may be suppressed and current leakage may be prevented.

### CROSS-REFERENCE TO RELATED APPLICATION(S)

This application claims priority to and the benefit of Korean Patent Application No. 10-2021-0106900 under 35 U.S.C. §119, filed in the Korean Intellectual Property Office (KIPO) on Aug. 12, 2021, and Korean Patent Application No. 10-2021-0146943 under 35 U.S.C. §119, filed in the Korean Intellectual Property Office (KIPO) on Oct. 29, 2021, the entire content of which is incorporated herein by reference.

### BACKGROUND

### 1. Technical Field

Embodiments relate to a display device and method of manufacturing the display device. More particularly, embodiments relate to a display device capable of displaying an image and method of manufacturing the display device.

### 2. Description of the Related Art

A display device may be manufactured and used in various ways. The display device may display light to provide visual information to the user. Such a display device may include a liquid crystal display device that emits light using a liquid crystal layer, an inorganic light emitting display device that emits light using an inorganic light emitting material, and an organic light emitting display device that emits light using an organic light emitting material.

The display device may emit light using various signals. Current may leak while the signals are transmitted to the liquid crystal layer, an inorganic light emitting diode, or an organic light emitting diode. In this case, a light emitting performance of the display device may be deteriorated.

Accordingly, various studies are being conducted to reduce an amount of current leaked when the signals are transmitted within the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments may provide a display device with improved display performance.

Embodiments may provide method of manufacturing a display device with improved display performance.

An embodiment of a display device may include a first active layer disposed on a substrate and including a source area, a resistance area, and a drain area spaced apart from the source area by the resistance area, a first gate electrode and a second gate electrode disposed on the first active layer and overlapping the first active layer, and a first power voltage electrode disposed on the first gate electrode and the second gate electrode and overlapping the resistance area in a cross-sectional view.

In an embodiment, the first active layer may include a first active area between the source area and the resistance area, and a second active area between the resistance area and the drain area, and in a cross-sectional view, the first gate electrode may overlap the first active area, and the second gate electrode overlaps the second active area.

In an embodiment, the first power voltage electrode may form a floating node capacitor with the resistance area of the first active layer.

In an embodiment, the display device may further include a second power voltage electrode disposed on the first power voltage electrode, and the second power voltage electrode may be electrically connected to the first power voltage electrode.

In an embodiment, the display device may further include a storage capacitor and the storage capacitor may include a third gate electrode, the third gate electrode and the second gate electrode being disposed on a same layer, and a storage capacitor electrode disposed on the third gate electrode and overlapping the third gate electrode.

In an embodiment, the storage capacitor may be electrically connected to the first active layer.

In an embodiment, the first gate electrode and the second gate electrode may form a dual gate transistor with the first active layer.

In an embodiment, the display device may further include a third gate electrode, the third gate electrode and the second gate electrode being disposed on a same layer, and a storage capacitor electrode disposed on the third gate electrode, overlapping the third gate electrode, and forming a storage capacitor with the third gate electrode, the first power voltage electrode may form a floating node capacitor with the resistance area of the first active layer, and the storage capacitor may be electrically connected to the first active layer.

In an embodiment, may further include a second active layer disposed on a same layer overlapping the third gate electrode, the first active layer and the second active layer being disposed on a same layer, a drain electrode disposed on the third gate electrode and electrically connected to the second active layer, and a light emitting element disposed on the drain electrode and electrically connected to the drain electrode.

An embodiment of a display device may include an active layer disposed on a substrate, and including a source area, a resistance area, and a drain area spaced apart from the source area by the resistance area, and a first power voltage electrode overlapping the resistance area in a cross-sectional view, the first power voltage electrode, the first gate electrode, and the second gate electrode being disposed on a same layer.

In an embodiment, the active layer may include a first active area between the source area and the resistance area, and a second active area between the resistance area and the drain area, in a cross-sectional view, the first gate electrode may overlap the first active area, and the second gate electrode overlaps the second active area, and the first power voltage electrode may form a floating node capacitor with the resistance area of the active layer.

In an embodiment, the display device may further include a second power voltage electrode disposed on the first power voltage electrode, the second power voltage electrode may be electrically connected to the first power voltage electrode.

An embodiment of a method of manufacturing a display device may include forming a first conductive layer on an active layer disposed on a substrate, forming a photoresist layer on the first conductive layer, exposing a first area of the photoresist layer corresponding to a transmissive area to expose the first conductive layer using a halftone mask, the halftone mask including a semi-transmissive area, a blocking area positioned on sides of the semi-transmissive area, and the transmissive area spaced apart from the semi-transmissive area by the blocking area, partially exposing a second area corresponding to the semi-transmissive area of the photoresist layer by using the halftone mask, forming a source area and a drain area by doping an impurity in an area overlapping the first area of the active layer, and forming a first gate electrode and a second gate electrode by etching an area of the first conductive layer that overlaps the second area.

In an embodiment, the exposing the first area of the photoresist layer and the partially exposing of the second area of the photoresist layer are performed at a same time.

In an embodiment, the doping of the impurity in the area overlapping the first area of the active layer may use the first conductive layer as a mask.

In an embodiment, the first gate electrode and the second gate electrode may form a dual gate transistor with the first active layer.

In an embodiment, a same signal may be applied to the first gate electrode and the second gate electrode.

In an embodiment, an area of the active layer overlapping the first gate electrode may be defined as a first active area, an area of the active layer overlapping the second gate electrode may be defined as a second active area, and an area of the active layer that is not doped with the impurity between the first active area and the second active area may be defined as a resistance area.

In an embodiment, the method may further include forming an insulating layer disposed to cover the first gate electrode and the second gate electrode, forming a second conductive layer on the insulating layer, and forming a power voltage electrode by etching an area of the second conductive layer corresponding to the first area, the first active area, and the second active area.

In an embodiment, the power voltage electrode may overlap the resistance area of the active layer, and the power voltage electrode may form a floating node capacitor with the resistance area of the active layer.

An embodiment of a display device may include a first active layer disposed on a substrate and including a source area, a resistance area, and a drain area spaced apart from the source area by the resistance area, a first gate electrode and a second gate electrode disposed on the first active layer and overlapping the first active layer, and a first power voltage electrode disposed on the first gate electrode and the second gate electrode and overlapping the resistance area in a cross-sectional view. In this case, the resistance area of the active layer and the first power voltage electrode may form a floating node capacitor.

Accordingly, when the first gate electrode and the second gate electrode form a dual gate transistor with the active layer, an instantaneous voltage increase may be suppressed and current leakage may be prevented.

In addition, when the display device may be manufactured using a halftone mask, a maskless process may be performed compared to the related art.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display device according to an embodiment.

FIG. 2 is a circuit diagram illustrating an embodiment of a pixel included in the display device of FIG. 1.

FIG. 3 is a schematic cross-sectional view illustrating an embodiment taken along line I-I′ of FIG. 1.

FIG. 4 is a schematic cross-sectional view illustrating an embodiment taken along line I-I′ of FIG. 1.

FIGS. 5, 6 and 7 are schematic views schematically illustrating a pixel layout corresponding to the cross-sectional view of FIG. 4.

FIGS. 8 and 9 are schematic views schematically illustrating a pixel layout corresponding to the cross-sectional view of FIG. 4.

FIGS. 10, 11, 12, 13, 14, 15, 16, 17, 18, 19, 20, 21 and 22 are schematic cross-sectional views illustrating an embodiment of manufacturing the display device of FIG. 1.

FIG. 23 is a block view illustrating an electronic device according to an embodiment.

FIG. 24 is a view illustrating an embodiment in which the electronic device of FIG. 23 is implemented as a television.

FIG. 25 is a view illustrating an embodiment in which the electronic device of FIG. 23 is implemented as a smartphone.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the disclosure may have diverse modified embodiments, various embodiments are illustrated in the drawings and are described in the detailed description. Advantages and features of the embodiments, and implementation methods thereof will be clarified through following embodiments described with reference to the accompanying drawings. The disclosure may, however, be embodied in many different forms and should not be construed as limited to the embodiments set forth herein.

It will be understood that although the terms “first,” “second,” etc. may be used herein to describe various components, these components should not be limited by these terms. These terms are only used to distinguish one element from another. For instance, a first element discussed below could be termed a second element without departing from the teachings of the disclosure. Similarly, the second element could also be termed the first element.

An expression used in the singular encompasses the expression of the plural, unless it has a clearly different meaning in the context.

It will be further understood that when the terms “comprises,” “comprising,” “includes” and/or “including”, “have” and/or “having” are used in this specification, they or it may specify the presence of stated features, integers, steps, operations, elements and/or components, but do not preclude the presence or addition of other features, integers, steps, operations, elements, components, and/or any combination thereof.

When a layer, film, region, substrate, or area, or element is referred to as being “on” another layer, film, region, substrate, or area, or element, it may be directly on the other film, region, substrate, or area, or element, or intervening films, regions, substrates, or areas, or elements may be present therebetween. Conversely, when a layer, film, region, substrate, or area, or element, is referred to as being “directly on” another layer, film, region, substrate, or area, or element, intervening layers, films, regions, substrates, or areas, may be absent therebetween. Further when a layer, film, region, substrate, or area, or element, is referred to as being “below” another layer, film, region, substrate, or area, or element, it may be directly below the other layer, film, region, substrate, or area, or element, or intervening layers, films, regions, substrates, or areas, or elements, may be present therebetween. Conversely, when a layer, film, region, substrate, or area, or element, is referred to as being “directly below” another layer, film, region, substrate, or area, or element, intervening layers, films, regions, substrates, or areas, or elements may be absent therebetween. Further, “over” or “on” may include positioning on or below an object and does not necessarily imply a direction based upon gravity.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

In the drawings, sizes and thicknesses of elements may be enlarged for better understanding, clarity, and ease of description thereof. However, the disclosure is not limited to the illustrated sizes and thicknesses. In the drawings, the thicknesses of layers, films, panels, regions, and other elements, may be exaggerated for clarity. In the drawings, for better understanding and ease of description, the thicknesses of some layers and areas may be exaggerated.

Further, in the specification, the phrase “in a plan view” means when an object portion is viewed from above, and the phrase “in a schematic cross-sectional view” means when a schematic cross-section taken by vertically cutting an object portion is viewed from the side.

Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first element may directly or indirectly oppose a second element. In a case in which a third element intervenes between the first and second element, the first and second element may be understood as being indirectly opposed to one another, although still facing each other. When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

When an embodiment may be implemented differently, a specific process order may be performed differently from the described order. For example, two consecutively described processes may be performed substantially at the same time or performed in an order opposite to the described order.

It will be understood that when a layer, region, or element is referred to as being “connected to” or “coupled to” another layer, region, or element, it can be directly connected or coupled to the other layer, region, or element or intervening layers, regions, or elements may be present. For example, as used herein, when a layer, region, or element is referred to as being “electrically connected to” another layer, region, or element, it can be directly electrically connected to the other layer, region, or element or intervening layers, intervening regions, or intervening elements may be present.

Also, when an element is referred to as being “in contact” or “contacted” or the like to another element, the element may be in “electrical contact” or in “physical contact” with another element; or in “indirect contact” or in “direct contact” with another element.

Unless otherwise defined, all terms (including technical and scientific terms) used herein have the same meaning as commonly understood by one of ordinary skill in the art to which embodiments pertain. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, the disclosure will be described in detail with reference to the accompanying drawings.

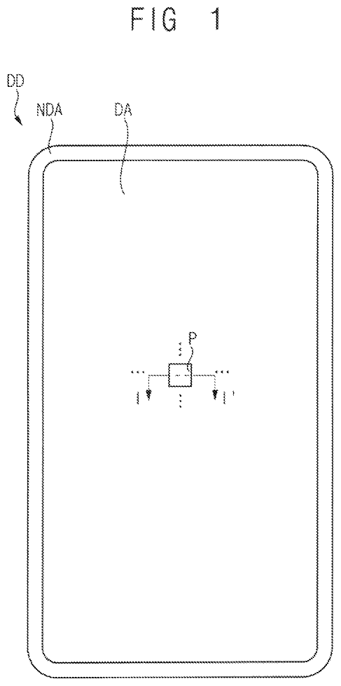

FIG. 1 is a schematic plan view illustrating a display device according to an embodiment.

Referring to FIG. 1, a display device DD may include a display area DA and a non-display area NDA. The non-display area NDA may be disposed to surround or adjacent to the display area DA. However, the non-display area NDA may be disposed only on at least one or a side of the display area DA.

Pixels P may be disposed in the display area DA. The pixels P may include a driving element (e.g., a transistor, etc.) and a light emitting element (e.g., an organic light emitting diode, etc.) electrically connected to the driving element. The light emitting element may emit light by receiving a signal from the driving element. As such, the display device DD may display an image by emitting light from the pixels P. The pixels P may be disposed in the display area DA. For example, the pixels P may be arranged or disposed in a matrix form in the display area DA.

A driver for driving the pixels P may be disposed in the non-display area NDA. The driver may include a data driver, a gate driver, a light emitting driver, a power voltage generator, a timing controller and the like. The pixels P may emit light based on signals received from the drivers.

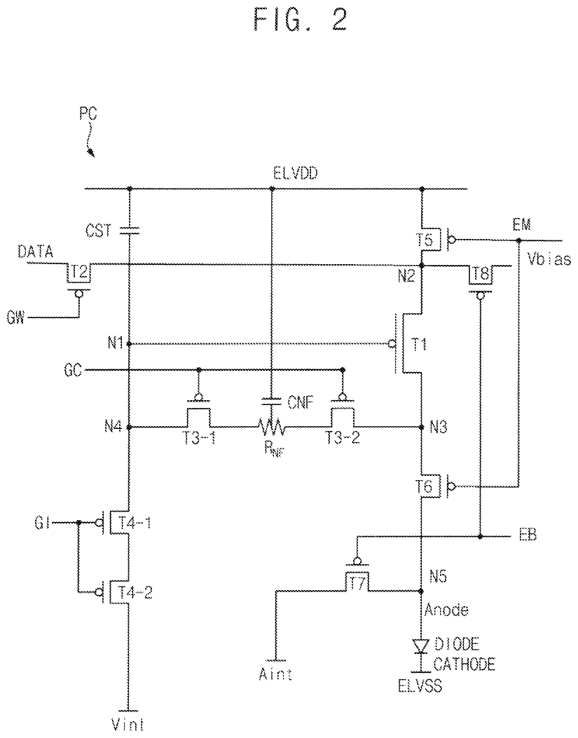

FIG. 2 is a circuit diagram illustrating an embodiment of a pixel included in the display device of FIG. 1.

Referring to FIGS. 1 and 2, the pixel P may include a pixel circuit PC and a diode. The pixel circuit PC may be electrically connected to the diode. The pixel circuit PC may include first to eighth transistors T1, T2, T3-1, T3-2, T4-1, T4-2, T5, T6, T7, T8, a storage capacitor CST, and a floating node capacitor CNF. However, the disclosure is not limited thereto.

The first transistor T1 may include a gate electrode, a first electrode, and a second electrode. The gate electrode of the first transistor T1 may be electrically connected to a first node N1. The first electrode of the first transistor T1 may be electrically connected to a second node N2. The second electrode of the first transistor T1 may be electrically connected to a third node N3. The second transistor T2 may include a gate electrode, a first electrode, and a second electrode. A data write signal GW may be applied to the gate electrode of the second transistor T2. A data voltage DATA may be applied to the first electrode of the second transistor T2. A second electrode of the second transistor T2 may be electrically connected to the second node N2. The third transistor may include a 3-1-th transistor T3-1 and a 3-2-th transistor T3-2 . The 3-1-th transistor T3-1 may include a gate electrode, a first electrode, and a second electrode. A compensation gate signal GC may be applied to the gate electrode of the 3-1-th transistor T3-1. The first electrode of the 3-1-th transistor T3-1 may be electrically connected to a fourth node N4. The second electrode of the 3-1-th transistor T3-1 may be electrically connected to the first electrode of the 3-2-th transistor T3-2. The 3-2-th transistor T3-2 may include a gate electrode, a first electrode, and a second electrode. The compensation gate signal GC may be applied to the gate electrode of the 3-2-th transistor T3-2. The first electrode of the 3-2-th transistor T3-2 may be electrically connected to the second electrode of the 3-1-th transistor T3-1. The second electrode of the 3-2-th transistor T3-2 may be electrically connected to the third node N3. As the third transistor is configured as a dual gate transistor, current leakage occurring in the pixel circuit PC may be prevented. The fourth transistor may include a 4-1-th transistor T4-1 and a 4-2-th transistor T4-2. The 4-1-th transistor T4-1 may include a gate electrode, a first electrode, and a second electrode. A data initialization gate signal GI may be applied to the gate electrode of the 4-1-th transistor T4-1. The first electrode of the 4-1-th transistor T4-1 may be electrically connected to the fourth node N4. The second electrode of the 4-1-th transistor T4-1 may be electrically connected to the first electrode of the 4-2-th transistor T4-2. The 4-2-th transistor T4-2 may include a gate electrode, a first electrode, and a second electrode. The data initialization gate signal GI may be applied to the gate electrode of the 4-2-th transistor T4-2. The first electrode of the 4-2-th transistor T4-2 may be electrically connected to the second electrode of the 4-1-th transistor T4-1. An initialization voltage Vint may be applied to the second electrode of the 4-2-th transistor T4-2. The fifth transistor T5 may include a gate electrode, a first electrode, and a second electrode. A light emitting signal EM may be applied to the gate electrode of the fifth transistor T5. A high power voltage ELVDD may be applied to the first electrode of the fifth transistor T5. The second electrode of the fifth transistor T5 may be electrically connected to the second node N2. The sixth transistor T6 may include a gate electrode, a first electrode, and a second electrode. The light emitting signal EM may be applied to the gate electrode of the sixth transistor T6. The first electrode of the sixth transistor T6 may be electrically connected to the third node N3. The second electrode of the sixth transistor T6 may be electrically connected to a fifth node N5. The seventh transistor T7 may include a gate electrode, a first electrode, and a second electrode. An initialization gate signal EB may be applied to the gate electrode of the seventh transistor T7. The first electrode of the seventh transistor T7 may be electrically connected to the fifth node N5. A diode initialization voltage Aint may be applied to the second electrode of the seventh transistor T7. The eighth transistor T8 may include a gate electrode, a first electrode, and a second electrode. An initialization gate signal EB may be applied to the gate electrode of the eighth transistor T8. The first electrode of the eighth transistor T8 may be electrically connected to the second node N2. A bias voltage Vbias may be applied to the second electrode of the eighth transistor T8. The storage capacitor CST may include a first electrode and a second electrode. A high power voltage ELVDD may be applied to the first electrode of the storage capacitor CST. The second electrode of the storage capacitor CST may be connected to the first node N1. The floating node capacitor CNF may include a first electrode and a second electrode. The high power voltage ELVDD may be applied to the first electrode of the floating node capacitor CNF. The second electrode of the floating node capacitor CNF may be electrically connected to the floating node resistor RNF between the third transistors T3-1 and T3-1. The diode may include an anode electrode and a cathode electrode. The anode electrode may be electrically connected to the fifth node N5. A low power voltage ELVSS may be applied to the cathode electrode.

In FIG. 2, the pixel circuit PC includes first to eighth transistors T1, T2, T3-1, T3-2, T4, T5, T6, T7, T8, a storage capacitor CST, and a floating node capacitor CNF, but this is illustrative and may not be limited thereto. For example, the pixel circuit PC may include various numbers of transistors and capacitors.

The dual gate transistor according to the above-described embodiments may be applied to transistors electrically connected to the capacitor CST.

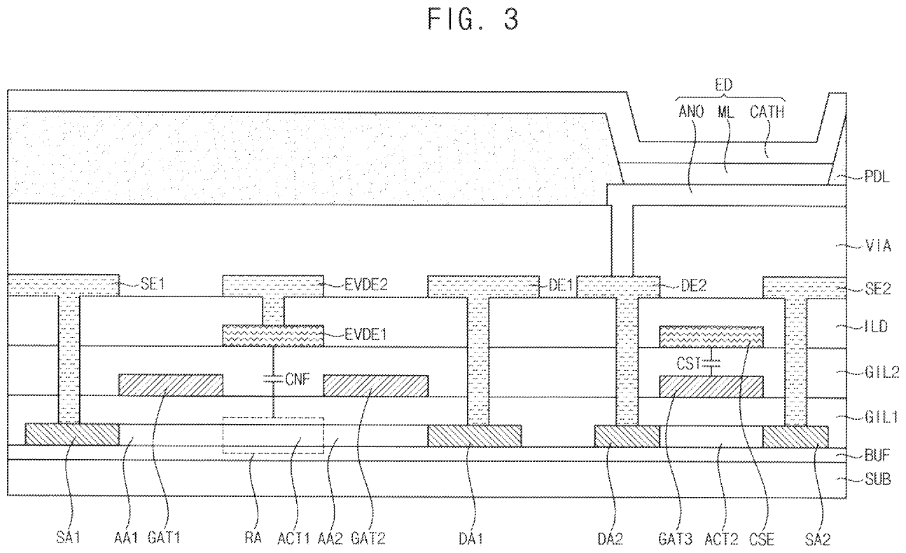

FIG. 3 is a schematic cross-sectional view illustrating an embodiment taken along line I-I′ of FIG. 1. FIG. 3 may be a schematic cross-sectional view illustrating a first transistor T1, third transistors T3-1 and T3-2, a storage capacitor CST, and a floating node capacitor CNF of FIG. 2.

Referring to FIGS. 1 to 3, a display device may include a substrate SUB, a buffer layer BUF, a first active layer ACT1, a second active layer ACT2, a first gate insulating layer GILL a first gate electrode GAT1, a second gate electrode GAT2, a third gate electrode GAT3, a second gate insulating layer GIL2, a first high power voltage electrode EVDE1, a storage capacitor electrode CSE, an interlayer insulating layer ILD, a first source electrode SE1, a first drain electrode DE1, a second high power voltage electrode EVDE2, a second source electrode SE2, a second drain electrode DE2, a via insulating layer VIA, a light emitting element ED and a pixel defining layer PDL. The light emitting element ED may include an anode electrode ANO, an intermediate layer ML, and a cathode electrode CATH. The light emitting element ED may correspond to the diode of FIG. 2. The first active layer ACT1 may include a first source area SA1 and a first drain area DA1. The first source area SA1 and the first drain area DA1 may be doped with impurities. The second active layer ACT2 may include a second source area SA2 and a second drain area DA2. In the second active layer ACT2, impurities may be doped into the second source area SA2 and the second drain area DA2.

The substrate SUB may include a flexible material or a rigid material. For example, the substrate SUB may include a polymer material such as polyimide, and in this case, the substrate SUB may have flexible properties. However, the disclosure is not limited thereto, for example, the substrate SUB may include a material such as glass, and in this case, the substrate SUB may have a rigid characteristic.

The buffer layer BUF may be disposed on the substrate SUB. The buffer layer BUF may include an inorganic insulating material. Examples of the material that can be used as the buffer layer BUF may include silicon oxide (“SiOx”), silicon nitride (“SiNx”), silicon oxynitride (“SiON”) and the like. These may be used alone or in combination with each other. The buffer layer BUF may prevent metal atoms or impurities from diffusing into the first and second active layers ACT1, ACT2. The buffer layer BUF may control speed of heat provided to the first and second active layers ACT1, ACT2 during a crystallization process for forming the first and second active layers ACT1, ACT2.

The first and second active layers ACT1, ACT2 may be disposed on the buffer layer BUF. In embodiments, the first and second active layers ACT1, ACT2 may include a silicon semiconductor. Examples of materials that can be used as the first and second active layers ACT1, ACT2 may include amorphous silicon and polycrystalline silicon, and the like. A center of the first active layer ACT1 may correspond to a resistance area RA. The resistance area RA may correspond to the floating node resistance R_{NF} of FIG. 2. The resistance area RA may not be doped with impurities and may not overlap the first and second gate electrodes GAT1, GAT2. A first active area AA1 may be positioned or formed between the resistance area RA of the first active layer ACT1 and the first source area SA1. A second active area AA2 may be positioned or formed between the resistance area RA of the first active layer ACT1 and the first drain area DA1.

The first gate insulating layer GIL1 may be disposed on the buffer layer BUF. The first gate insulating layer GIL1 may be disposed to overlap or cover the first and second active layers ACT1, ACT2. The first gate insulating layer GIL1 may include an insulating material. Examples of the material that can be used as the first gate insulating layer GIL1 may include silicon oxide (“SiOx”), silicon nitride (“SiNx”), silicon oxynitride (“SiON”), and the like. These may be used alone or in combination with each other.

The first to third gate electrodes GAT1, GAT2, GAT3 may be disposed on the first gate insulating layer GILL The first and second gate electrodes GAT1, GAT2 may partially overlap the first active layer ACT1. For example, the first gate electrode GAT1 may overlap the first active area AA1 of the first active layer ACT1 in a cross-sectional view. The second gate electrode GAT2 may overlap the second active area AA2 of the first active layer ACT1 in a cross-sectional view. The first gate electrode GAT1 and the second gate electrode GAT2 may form a dual gate transistor with the first active layer ACT1. The same signal may be applied to the first gate electrode GAT1 and the second gate electrode GAT2.

The third gate electrode GAT3 may partially overlap the second active layer ACT2. In response to a gate signal provided to the first and second gate electrodes GAT1, GAT2, a signal and/or a voltage may flow through the first active layer ACT1. In response to a gate signal provided to the third gate electrode GAT3, a signal and/or a voltage may flow through the second active layer ACT2. In an embodiment, the first to third gate electrodes GAT1, GAT2, GAT3 may include a metal, an alloy, a metal oxide, a transparent conductive material, or the like. Examples of materials that can be used as the first to third gate electrodes GAT1, GAT2, GAT3 may include silver (“Ag”), an alloy containing silver, molybdenum (“Mo”), an alloy containing molybdenum, Aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide ITO, indium zinc oxide IZO, and the like. These may be used alone or in combination with each other.

The second gate insulating layer GIL2 may be disposed on the first gate insulating layer GILL The second gate insulating layer GIL2 may be disposed to overlap or cover the first to third gate electrodes GAT1, GAT2, GAT3. The second gate insulating layer GIL2 may include an insulating material. Examples of the material that can be used as the second gate insulating layer GIL2 may include silicon oxide (“SiOx”), silicon nitride (“SiNx”), silicon oxynitride (“SiON”), and the like. These may be used alone or in combination with each other.

The first high power voltage electrode EVDE1 and the storage capacitor electrode CSE may be disposed on the second gate insulating layer GIL2. The high power voltage ELVDD may be applied to the first high power voltage electrode EVDE1. The first high power voltage electrode EVDE1 may not overlap the first gate electrode GAT1 and the second gate electrode GAT2. Accordingly, the floating node capacitor CNF may be formed between the first high power voltage electrode EVDE1 and the first active layer ACT1. The floating node capacitor CNF may suppress an instantaneous voltage increase in the third transistors T3-1 and T3-2, and current leakage from the third transistors T3-1 and T3-2 may be prevented.

The embodiment described with reference to the third transistors T3-1 and T3-2 may be applied to the fourth transistors T4-1 and T4-2. For example, the embodiment described with reference to the third transistors T3-1 and T3-2 may be applied to transistors electrically connected to the storage capacitor CST. In an embodiment, the active layer ACT1 of the third transistors T3-1 and T3-2 may be electrically connected to the third gate electrode GAT3. In another embodiment, the active layers of the fourth transistors T4-1 and T4-2 may be electrically connected to the third gate electrode GAT3.

The storage capacitor electrode CSE may overlap the third gate electrode GAT3. Accordingly, the storage capacitor CST may be formed between the storage capacitor electrode CSE and the third gate electrode GAT3. The storage capacitor electrode CSE may store a constant voltage so that the first transistor T1 may be stably driven.

The interlayer insulating layer ILD may be disposed on the second gate insulating layer GIL2. The interlayer insulating layer ILD may be disposed to overlap or cover the first high power voltage electrode EVDE1 and the storage capacitor electrode CSE. In an embodiment, the interlayer insulating layer ILD may include an insulating material. Examples of the material that can be used as the interlayer insulating layer ILD may include silicon oxide (“SiOx”), silicon nitride (“SiNx”), silicon oxynitride (“SiON”), and the like. These may be used alone or in combination with each other.

The first source electrode SE1, the second source electrode SE2, the first drain electrode DE1, and the second drain electrode DE2 may be disposed on the interlayer insulating layer ILD. The first source electrode SE1 may contact (e.g., directly contact) the source area SA1 of the first active layer ACT1 through a contact hole. The first drain electrode DE1 may contact (e.g., directly contact) the second drain area DA1 of the first active layer ACT1 through a contact hole. The second source electrode SE2 may contact (e.g., directly contact) the second source area SA2 of the second active layer ACT2 through a contact hole. The second drain electrode DE2 may contact (e.g., directly contact) the second drain area DA2 of the second active layer ACT2 through a contact hole. In an embodiment, the first source electrode SE1, the second source electrode SE2, the first drain electrode DE1, and the second drain electrode DE2 may each include a metal, an alloy, a metal oxide, a transparent conductive material, or the like. Examples of materials that can be used as the first source electrode SE1, the second source electrode SE2, the first drain electrode DE1, and the second drain electrode DE2 may include silver (“Ag”), an alloy containing silver, molybdenum (“Mo”), an alloy containing molybdenum, Aluminum (“Al”), alloys containing aluminum, aluminum nitride (“AlN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide ITO, indium zinc oxide IZO, and the like. These may be used alone or in combination with each other.

The second high power voltage electrode EVDE2 may be disposed on the interlayer insulating layer ILD. The second high power voltage electrode EVDE2 may be formed simultaneously with the first source electrode SE1. The second high power voltage electrode EVDE2 and the first source electrode SE1 may include a same material. For example, the second high power voltage electrode EVDE2may include a same material as the first source electrode SE1. The second high power voltage electrode EVDE2 may be electrically connected to the first high power voltage electrode EVDE1 through a contact hole. The high power voltage ELVDD applied to the second high power voltage electrode EVDE2 may be transferred to the first high power voltage electrode EVDE1.

The first active layer ACT1, the first gate electrode GAT1, the second gate electrode GAT2, the first source electrode SE1, and the first drain electrode DE1 may constitute or form the third transistors T3-1 and T3-2. The second active layer ACT2, the third gate electrode GAT3, the second source electrode SE2, and the second drain electrode DE2 may constitute or form the first transistor T1.

The via insulating layer VIA may be disposed on the interlayer insulating layer ILD. The via insulating layer VIA may be disposed to overlap or cover the first source electrode SE1, the second source electrode SE2, the first drain electrode DE1, and the second drain electrode DE2. The via insulating layer VIA may have a substantially flat top surface. In an embodiment, the via insulating layer VIA may include an organic insulating material. Examples of the material that can be used as the via insulating layer VIA may include a photoresist, a polyacrylic resin, a polyimide resin, an acrylic resin, and the like. These may be used alone or in combination with each other.

The anode electrode ANO may be disposed on the via insulating layer VIA. The anode electrode ANO may pass through the via insulating layer VIA to be electrically connected to the second drain electrode DE2. For example, the anode electrode ANO may pass through the via insulating layer VIA through a contact hole. In an embodiment, the anode electrode ANO may include a metal, an alloy, a metal oxide, a transparent conductive material, or the like. Examples of materials that can be used as the anode electrode ANO may include silver (“Ag”), an alloy containing silver, molybdenum (“Mo”), an alloy containing molybdenum, Aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide ITO, indium zinc oxide IZO, and the like. These may be used alone or in combination with each other.

The pixel defining layer PDL may be disposed on the via insulating layer VIA. An opening exposing the anode electrode ANO may be formed in the pixel defining layer PDL. In an embodiment, the pixel defining layer PDL may include an organic material. Examples of materials that can be used as the pixel defining layer PDL may include photoresists, polyacrylic resins, polyimide resins, and acrylic resins, and the like.

The intermediate layers ML may be disposed on the anode electrodes ANO. The intermediate layer ML may include an organic material emitting light of a preset color (red, green, blue, etc.). The intermediate layer ML may emit light based on a potential difference between the anode electrode ANO and the cathode electrode CATH. For example, the intermediate layer ML may include an electron injection layer, an electron transport layer, a light emitting layer, a hole transport layer, and a hole injection layer, respectively.

The cathode electrode CATH may be disposed on the intermediate layers ML. In an embodiment, the cathode electrode CATH may include silver metal, an alloy, a metal oxide, a transparent conductive material, or the like. Examples of materials that can be used as the cathode electrode CATH may include silver (“Ag”), an alloy containing silver, molybdenum (“Mo”), an alloy containing molybdenum, Aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide ITO, indium zinc oxide IZO, and the like. These may be used alone or in combination with each other.

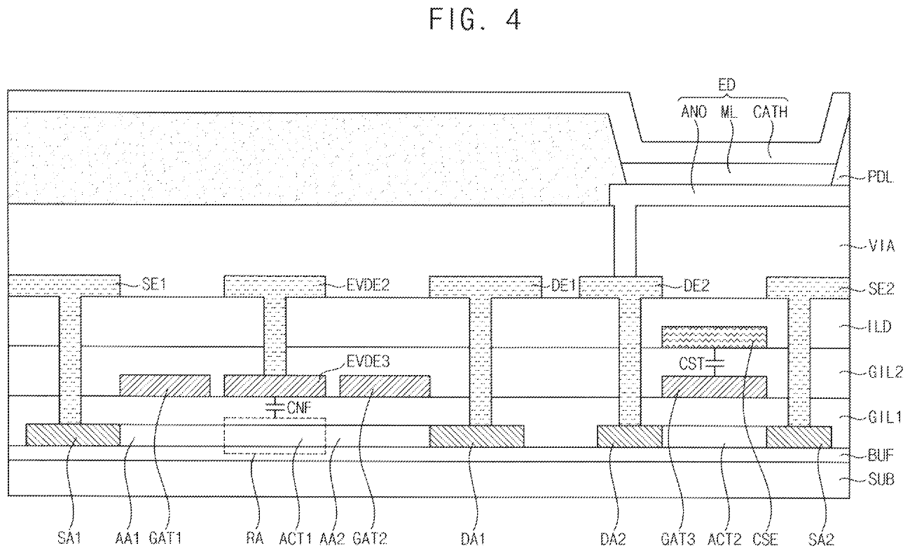

FIG. 4 is a schematic cross-sectional view illustrating another embodiment taken along line I-I′ of FIG. 1. FIG. 4 may be substantially similar as FIG. 3 except that a third high power voltage electrode EVDE3 is disposed instead of the first high power voltage electrode EVDE1. Accordingly, a description of the similar configuration will be omitted.

Referring to FIGS. 1, 2, and 4, the third high voltage electrode EVDE3, the first gate electrode GAT1, and the second gate electrode GAT2 may be disposed on a same layer. For example, the third high voltage electrode EVDE3 may be disposed on a same layer as the first gate electrode GAT1 and the second gate electrode GAT2. The third high power voltage electrode EVDE3 may be disposed to overlap the resistance area RA. For example, the third high power voltage electrode EVDE3 may be disposed to overlap only the resistance area RA. The third high power voltage electrode EVDE3 may form the resistance area RA and the floating node capacitor CNF.

The third high power voltage electrode EVDE3 may be electrically connected to the second high power voltage electrode EVDE2. Accordingly, a same voltage may be applied to the second high power voltage electrode EVDE2 and the third high power voltage electrode EVDE3. For example, a same voltage as the voltage applied to the second high power voltage electrode EVDE2 may be applied to the third high power voltage electrode EVDE3.

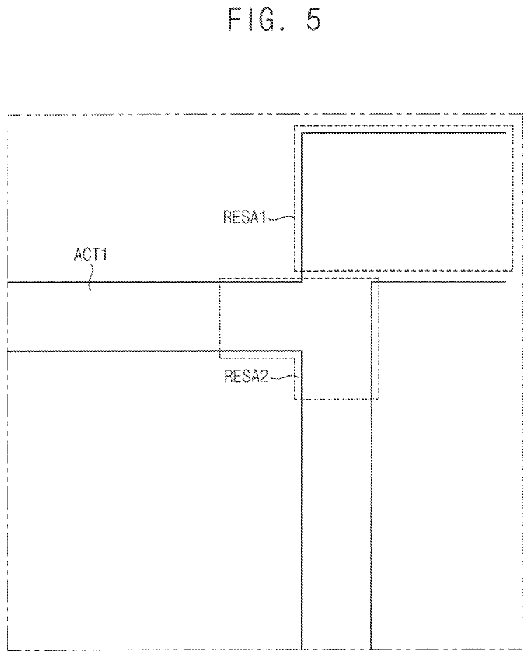

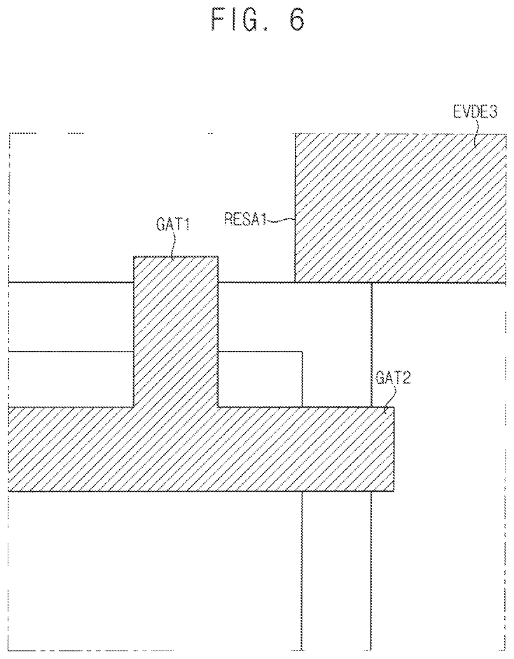

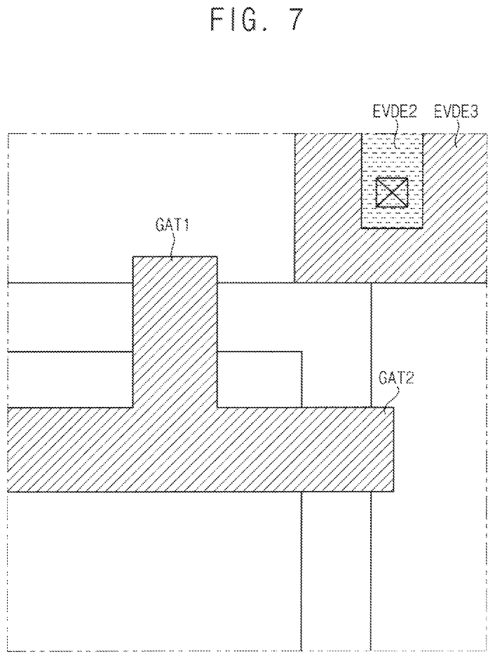

FIGS. 5 to 7 are schematic views schematically illustrating a pixel layout corresponding to the cross-sectional view of FIG. 4.

Referring to FIGS. 4 to 7, the first gate electrode GAT1, the second gate electrode GAT2, and the third high power voltage electrode EVDE3 may be disposed to overlap the first active layer ACT1. A portion where the first gate electrode GAT1 overlaps the first active layer ACT1 may correspond to the first active area AA1 of FIG. 4. A portion where the second gate electrode GAT2 overlaps the first active layer ACT1 may correspond to the second active area AA2 of FIG. 4. The third high voltage electrode EVDE3 may be disposed to overlap a first area RESA1 of the first active layer ACT1. A portion where the third high voltage electrode EVDE3 overlaps the first active layer ACT1 may correspond to the resistance area RA of FIG. 4.

The second high power voltage electrode EVDE2 may be disposed on the third high power voltage electrode EVDE3 and may be electrically connected to the third high power voltage electrode EVDE3 through a contact hole.

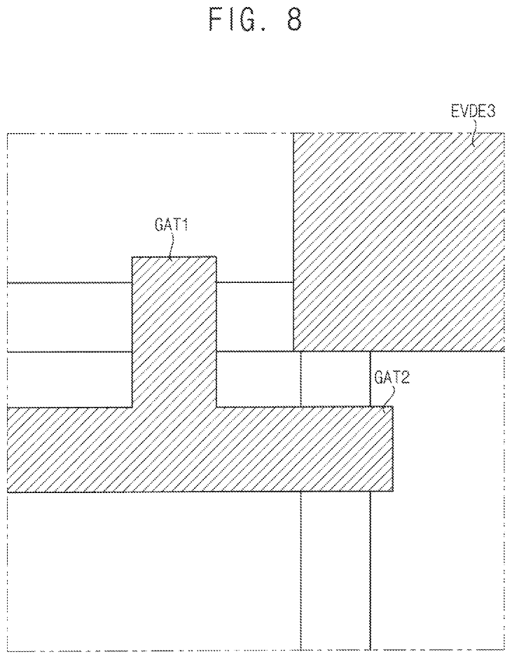

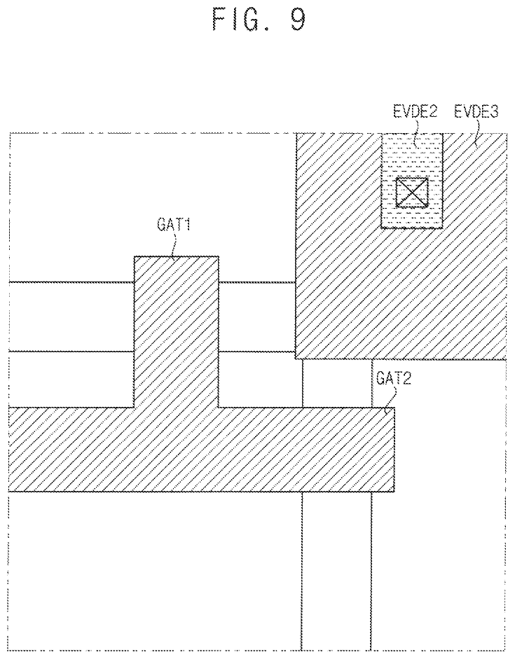

FIGS. 8 and 9 are schematic views schematically illustrating a pixel layout corresponding to the cross-sectional view of FIG. 4.

Referring to FIGS. 4, 5, 8, and 9, the first gate electrode GAT1, the second gate electrode GAT2, and the third high power voltage electrode EVDE3 may be disposed to overlap the first active layer ACT1. A portion where the first gate electrode GAT1 overlaps the first active layer ACT1 may correspond to the first active area AA1 of FIG. 4. A portion where the second gate electrode GAT2 overlaps the first active layer ACT1 may correspond to the second active area AA2 of FIG. 4. The third high voltage electrode EVDE3 may be disposed to overlap the first area RESA1 of the first active layer ACT1 and overlap a second area RESA2. For example, the third high voltage electrode EVDE3 may be disposed to entirely overlap the first area RESA1 of the first active layer ACT1 and partially overlap the second area RESA2. A portion where the third high voltage electrode EVDE3 overlaps the first active layer ACT1 may correspond to the resistance area RA of FIG. 4.

The second high power voltage electrode EVDE2 may be disposed on the third high power voltage electrode EVDE3 and may be electrically connected to the third high power voltage electrode EVDE3 through a contact hole.

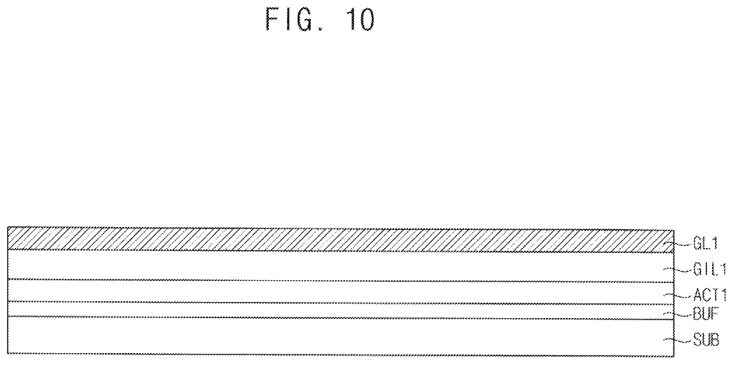

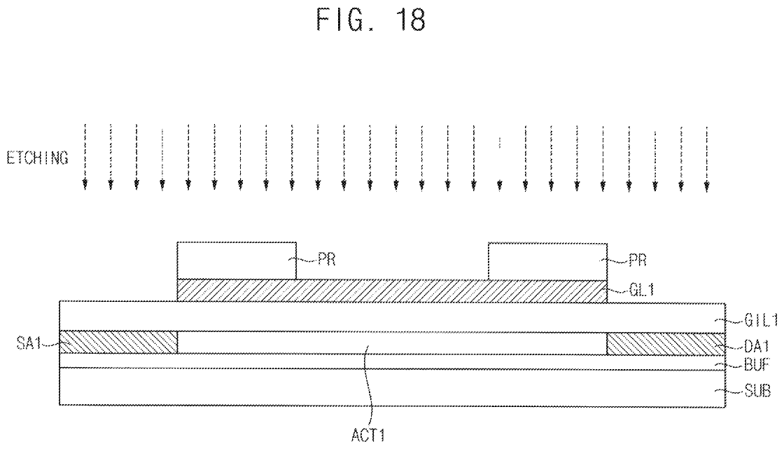

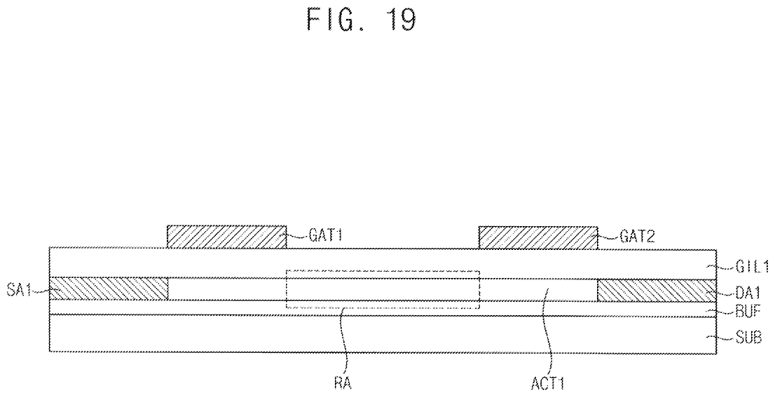

FIGS. 10 to 22 are schematic cross-sectional views illustrating an embodiment of manufacturing the display device of FIG. 1.

Referring to FIG. 10, a substrate SUB, a buffer layer BUF, a first active layer ACT1 and a first gate insulating layer GIL1 may be stacked or formed. A first conductive layer GL1 may be formed on the first gate insulating layer GIL1.

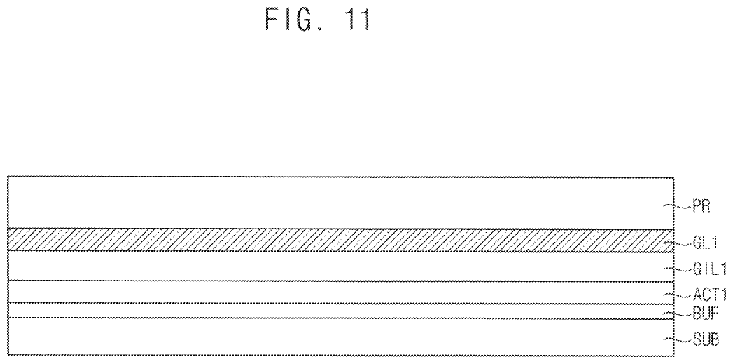

Referring to FIG. 11, a photoresist layer PR may be formed on the first gate insulating layer GIL1. The photoresist layer PR may include a photosensitive material.

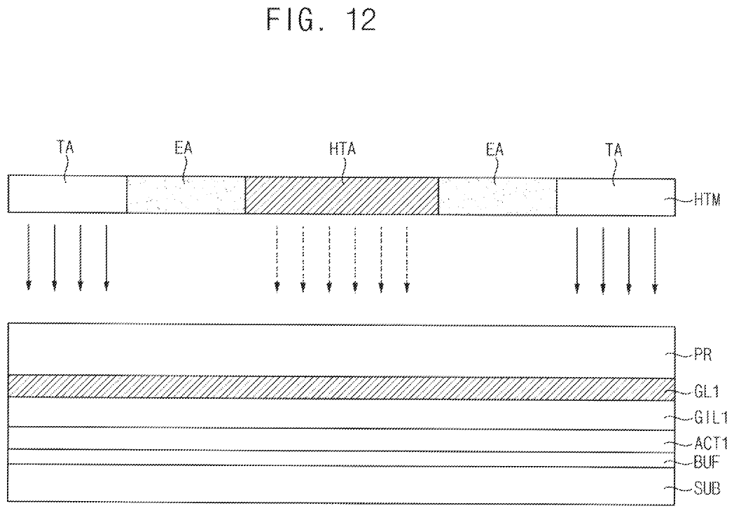

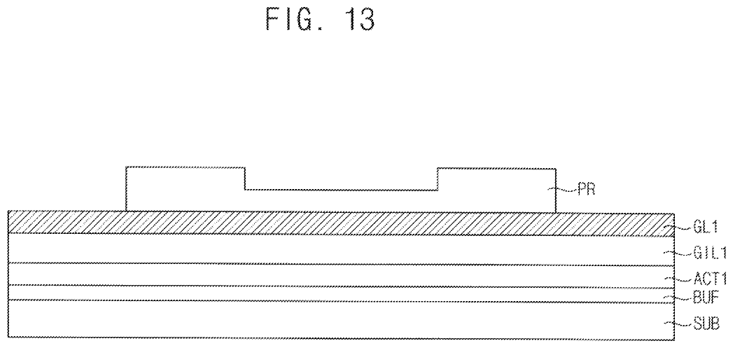

Referring to FIGS. 12 and 13, an exposure process may be performed using a halftone mask HTM. The photoresist layer PR may be exposed to different degrees by using a difference in exposure amount between transmissive areas TA and semi-transmissive areas HTA of the halftone mask HTM. By using the halftone mask HTM, the photoresist layer PR may be exposed to different degrees depending on an area. Exposure may not proceed in blocking area EA of the halftone mask HTM. For example, area corresponding to the semi-transmissive area HTA of the photoresist layer PR may be etched relatively less than an area corresponding to the transmissive area TA of the photoresist layer PR.

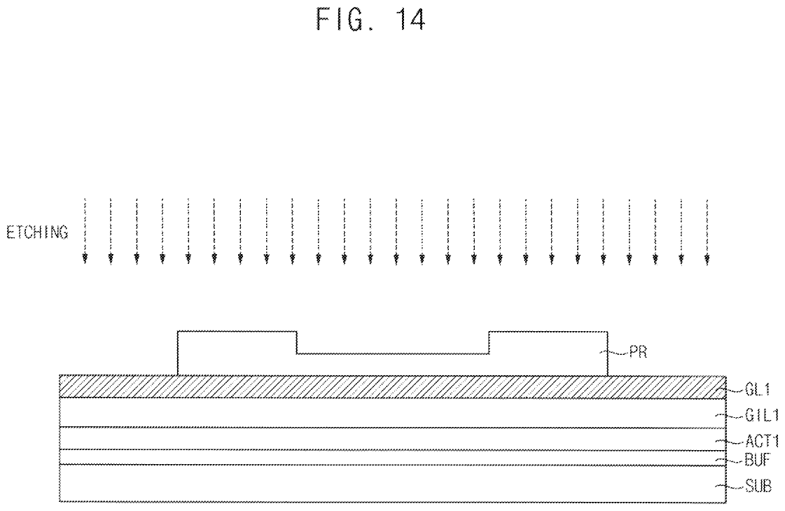

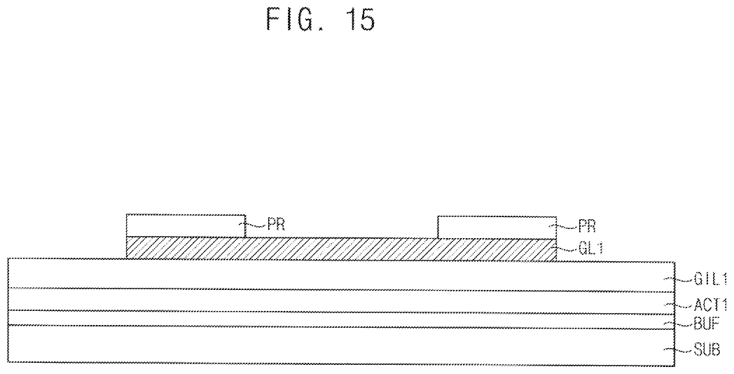

Referring to FIGS. 14 and 15, the photoresist layer PR and the first conductive layer GL1 may be partially etched by an etching process. In an embodiment, the etching process may be performed by dry etching. An area of the first conductive layer GL1 not overlapped or covered by the photoresist layer PR may be removed by the etching process. Also, an area of the photoresist layer PR that overlaps the semi-transmissive area HTA may be removed by the etching process.

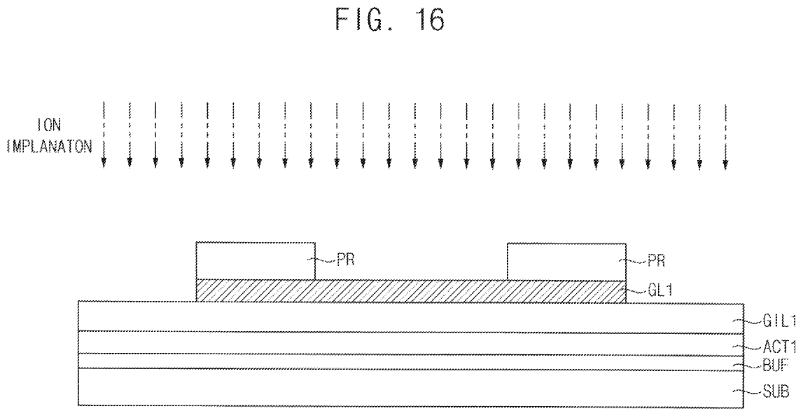

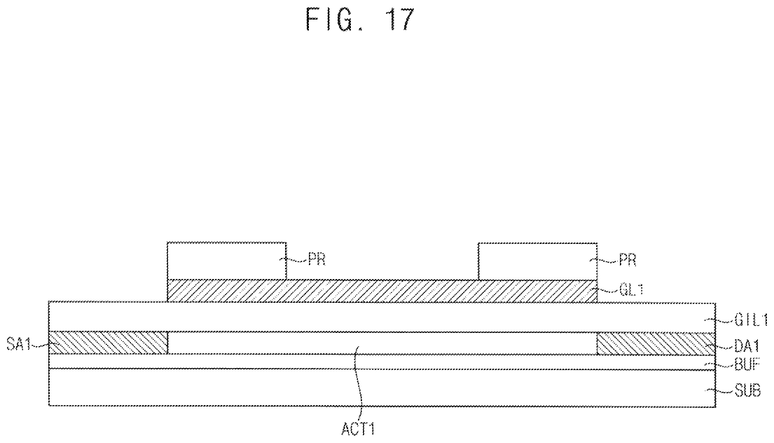

Referring to FIGS. 16 and 17, the first active layer ACT1 may be doped with impurities. The impurities may be ions. A first source area SA1 and a first drain area DA1 may be formed at ends of the first active layer ACT1 by an ion implantation process.

Referring to FIGS. 2, 3, 18, and 19, the etching process may be performed again. In an embodiment, the etching process may be performed by dry etching. An area of the photoresist layer PR and the remaining first conductive layer GL1 may be etched by the etching process to form the first gate electrode GAT1 and the second gate electrode GAT2. In this case, the first conductive layer GL1 may serve as a mask, such that the resistance area RA may not be doped with impurities. Accordingly, the resistance area RA may have a higher resistance than the first source area SA1 and the first drain area DA1. Accordingly, the third transistors T3-1 and T3-2 may have effects such as preventing an instantaneous voltage rise and reducing leakage current through VDS reduction.

In a case that the halftone mask HTM is used, a dual gate transistor and a floating node capacitor may be realized using a relatively small amount of mask compared to the related art.

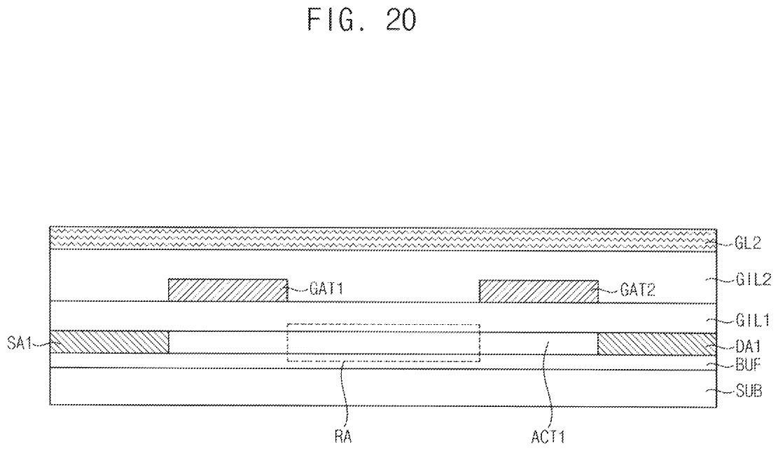

Referring to FIG. 20, a second gate insulating layer GIL2 may be formed on the first gate insulating layer GIL1. Thereafter, a second conductive layer GL2 may be formed on the second gate insulating layer GIL2.

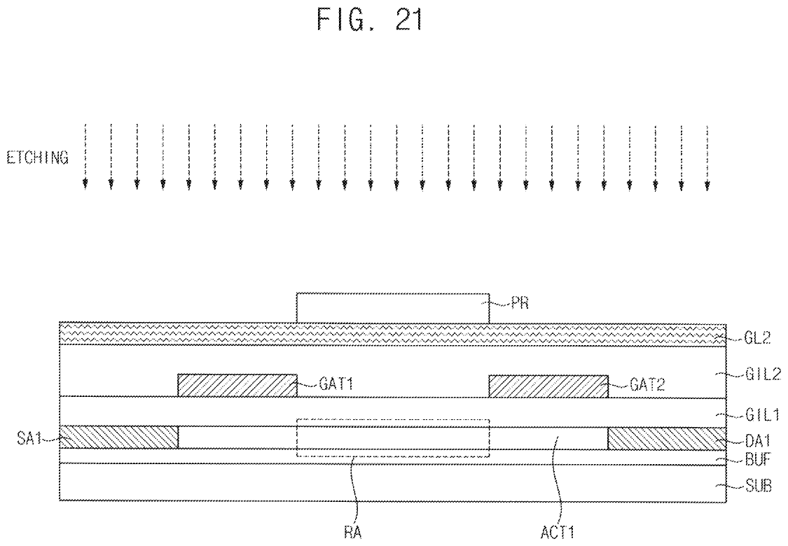

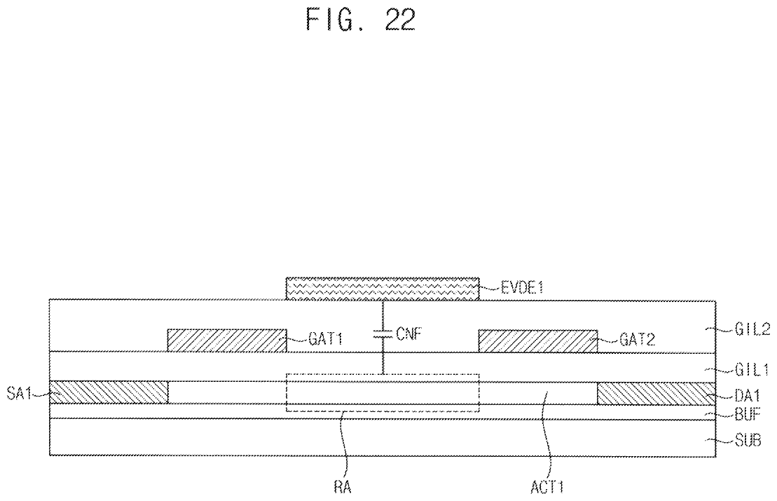

Referring to FIGS. 21 and 22, the photoresist layer PR may be formed again on the second conductive layer GL2. An etching process for the second conductive layer GL2 may be performed. Accordingly, the first high power voltage electrode EVDE1 may be formed, and the first high power voltage electrode EVDE1 may form the floating node capacitor CNF together with the first active layer ACT1.

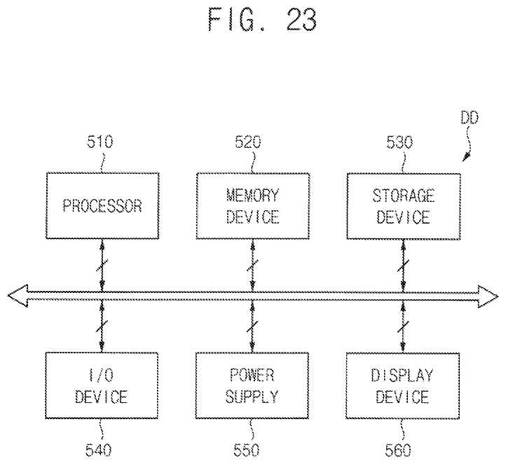

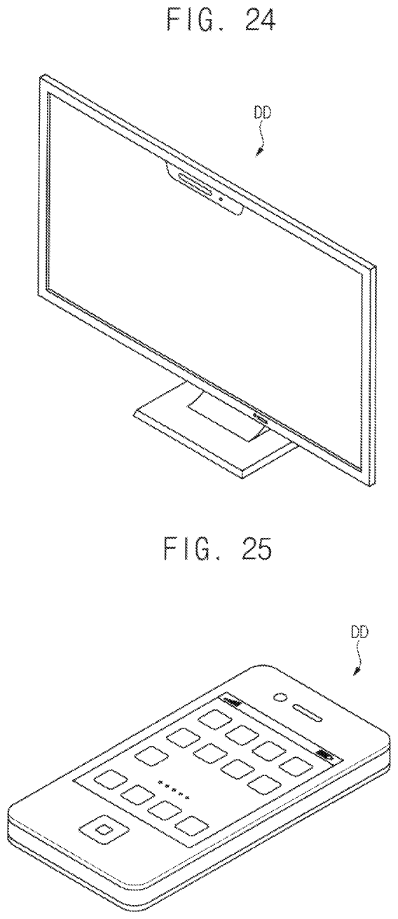

FIG. 23 is a block view illustrating an electronic device according to an embodiment, FIG. 24 is a schematic view illustrating an embodiment in which the electronic device of FIG. 23 is implemented as a television, and FIG. 25 is a view illustrating an embodiment in which the electronic device of FIG. 23 is implemented as a smartphone.

Referring to FIGS. 23 to 25, an embodiment of an electronic device DD may include a processor 510, a memory device 520, a storage device 530, an input/output device 540, a power supply 550, and a display device 560. In an embodiment, the display device 560 may correspond to the display device described above with reference to the above drawings. The electronic device DD may further include several ports capable of communicating with a video card, a sound card, a memory card, a USB device, and the like. In an embodiment, as illustrated in FIG. 24, the electronic device DD may be implemented as a television. In an embodiment, as illustrated in FIG. 25, the electronic device DD may be implemented as a smartphone. However, the electronic device DD is not limited thereto, and for example, the electronic device DD may include a mobile phone, a video phone, a smart pad, a smart watch, a tablet PC, a vehicle navigation system, it may be implemented as a computer monitor, notebook computer, head mounted display (“HMD”), or the like.

The processor 510 may perform calculations or tasks. In an embodiment, the processor 510 may be a micro processor, a central processing unit (“CPU”), an application processor (“AP”), or the like. The processor 510 may be connected to other components through an address bus, a control bus, a data bus, or the like. In an embodiment, the processor 510 may also be connected to an expansion bus such as a peripheral component interconnect (“PCI”) bus.

The memory device 520 may store data used for the operation of the electronic device DD. In an embodiment, for example, the memory device 520 may include nonvolatile memory device such as an erasable programmable read-only memory (“EPROM”) device, an electrically erasable programmable read-only memory (“EEPROM”) device, a flash memory device, and a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and/or volatile memory device such as a dynamic random access memory (“DRAM”) device, a static random access memory (“SRAM”) device, a mobile DRAM device, or the like.

The storage device 530 may include a solid state drive (“SSD”), a hard disk drive (“HDD”), a CD-ROM, or the like. The input/output device 540 may include an input means such as a keyboard, a keypad, a touch pad, a touch screen, and a mouse, or the like, and an output means such as a speaker and a printer, or the like.

The power supply 550 may supply power required for the operation of the electronic device DD. The display device 560 may be coupled to other components via buses or other communication links. According to an embodiment, the display device 560 may be included in the input/output device 540.

Embodiments of the display device may be applied to a display device included in a computer, a notebook, a mobile phone, a smartphone, a smart pad, a personal media player (“PMP”), a personal digital assistant (“PDA”), an MP3 player, or the like.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device, comprising:
a first active layer disposed on a substrate and including a source area, a resistance area, and a drain area spaced apart from the source area by the resistance area;
a first gate electrode and a second gate electrode disposed on the first active layer and overlapping the first active layer; and
a first power voltage electrode disposed on the first gate electrode and the second gate electrode and overlapping the resistance area in a cross-sectional view.

2. The display device of claim 1, wherein
the first active layer includes:
a first active area between the source area and the resistance area; and
a second active area between the resistance area and the drain area, and
in a cross-sectional view, the first gate electrode overlaps the first active area, and the second gate electrode overlaps the second active area.

3. The display device of claim 1, wherein the first power voltage electrode forms a floating node capacitor with the resistance area of the first active layer.

4. The display device of claim 1, further comprising:
a second power voltage electrode disposed on the first power voltage electrode, wherein
the second power voltage electrode is electrically connected to the first power voltage electrode.

5. The display device of claim 1, further comprising a storage capacitor, wherein the storage capacitor includes:
a third gate electrode, the third gate electrode and the second gate electrode being disposed on a same layer; and
a storage capacitor electrode disposed on the third gate electrode and overlapping the third gate electrode.

6. The display device of claim 5, wherein the storage capacitor is electrically connected to the first active layer.

7. The display device of claim 1, wherein the first gate electrode and the second gate electrode form a dual gate transistor with the first active layer.

8. The display device of claim 1, further comprising:
a third gate electrode, the third gate electrode and the second gate electrode being disposed on a same layer; and
a storage capacitor electrode disposed on the third gate electrode, overlapping the third gate electrode, and forming a storage capacitor with the third gate electrode, wherein
the first power voltage electrode forms a floating node capacitor with the resistance area of the first active layer, and
the storage capacitor is electrically connected to the first active layer.

9. The display device of claim 8, further comprising:
a second active layer overlapping the third gate electrode, the first active layer and the second active layer being disposed on a same layer;
a drain electrode disposed on the third gate electrode and electrically connected to the second active layer; and
a light emitting element disposed on the drain electrode and electrically connected to the drain electrode.

10. A display device, comprising:
an active layer disposed on a substrate and including a source area, a resistance area, and a drain area spaced apart from the source area by the resistance area; and
a first power voltage electrode overlapping the resistance area in a cross-sectional view, the first power voltage electrode, the first gate electrode, and the second gate electrode being disposed on a same layer.

11. The display device of claim 10, wherein
the active layer includes:
a first active area between the source area and the resistance area; and
a second active area between the resistance area and the drain area,
in a cross-sectional view, the first gate electrode overlaps the first active area, and the second gate electrode overlaps the second active area, and
the first power voltage electrode forms a floating node capacitor with the resistance area of the active layer.

12. The display device of claim 11, further comprising:
a second power voltage electrode disposed on the first power voltage electrode, wherein
the second power voltage electrode is electrically connected to the first power voltage electrode.

13. A method of manufacturing a display device, comprising:
forming a first conductive layer on an active layer disposed on a substrate;
forming a photoresist layer on the first conductive layer;
exposing a first area of the photoresist layer corresponding to a transmissive area to expose the first conductive layer using a halftone mask, the halftone mask including a semi-transmissive area, a blocking area positioned on sides of the semi-transmissive area, and the transmissive area spaced apart from the semi-transmissive area by the blocking area;
partially exposing a second area corresponding to the semi-transmissive area of the photoresist layer by using the halftone mask;
forming a source area and a drain area by doping an impurity in an area overlapping the first area of the active layer; and
forming a first gate electrode and a second gate electrode by etching an area of the first conductive layer that overlaps the second area.

14. The method of claim 13, wherein the exposing of the first area of the photoresist layer and the partially exposing of the second area of the photoresist layer are performed at a same time.

15. The method of claim 13, wherein the doping of the impurity in the area overlapping the first area of the active layer uses the first conductive layer as a mask.

16. The method of claim 13, wherein the first gate electrode and the second gate electrode form a dual gate transistor with the first active layer.

17. The method of claim 16, wherein a same signal is applied to the first gate electrode and the second gate electrode.

18. The method of claim 13, wherein
an area of the active layer overlapping the first gate electrode is defined as a first active area,
an area of the active layer overlapping the second gate electrode is defined as a second active area, and
an area of the active layer that is not doped with the impurity between the first active area and the second active area is defined as a resistance area.

19. The method of claim 18, further comprising:
forming an insulating layer disposed to cover the first gate electrode and the second gate electrode;
forming a second conductive layer on the insulating layer; and
forming a power voltage electrode by etching an area of the second conductive layer corresponding to the first area, the first active area, and the second active area.

20. The method of claim 19, wherein
the power voltage electrode overlaps the resistance area of the active layer, and
the power voltage electrode forms a floating node capacitor with the resistance area of the active layer.
